(19) United States
(12) Patent Application Publication
(10) Pub. No.: US 2015/0228329 A1
(43) Pub. Date: Aug. 13, 2015

(54) SEMICONDUCTOR DEVICES AND SEMICONDUCTOR SYSTEMS INCLUDING THE SAME

(71) Applicant: SK hynix Inc., Icheon-si Gyeonggi-do (KR)

(72) Inventor: Sang Il PARK, Suwon-si Gyeonggi-do (KR)

(21) Appl. No.: 14/301,422

(22) Filed: Jun. 11, 2014

(30) Foreign Application Priority Data
Feb. 13, 2014 (KR) 10-2014-0016886

(51) Int. Cl. G11C 11/406

(52) U.S. Cl. CPC G11C 11/40615; G11C 11/40618

(57) ABSTRACT

The semiconductor device includes a mode signal generator and a refresh controller. The mode signal generator generates a mode signal. The refresh controller generates a first bank active signal and a second bank active signal sequentially enabled in response to the mode signal and a section signal. The second bank active signal is enabled while the first bank active signal is enabled if the mode signal has a first level. The second bank active signal is enabled while the first bank active signal is disabled after the first bank active signal is enabled if the mode signal has a second level.

### CROSS-REFERENCE TO RELATED APPLICATION

The present application claims priority under 35 U.S.C 119(a) to Korean Application No. 10-2014-0016886, filed on Feb. 13, 2014, in the Korean Intellectual Property Office, which is incorporated herein by reference in its entirety as set forth in full.

### BACKGROUND

1. Technical Field

Embodiments of the invention relate to semiconductor devices and semiconductor systems including the same.

2. Related Art

Dynamic random access random (DRAM) devices of semiconductor devices may lose their stored data as the time elapses even though their power voltages are supplied, unlike static random access random (SRAM) devices and flash memory devices. This may be due to leakage currents of cell capacitors constituting memory cells of the DRAM devices together with cell transistors.

### SUMMARY

According to an embodiment, a semiconductor device includes a mode signal generator and a refresh controller. The mode signal generator generates a mode signal. The refresh controller generates a first bank active signal and a second bank active signal sequentially enabled in response to the mode signal and a section signal. The second bank active signal is enabled while the first bank active signal is enabled if the mode signal has a first level. In addition, the second bank active signal is enabled while the first bank active signal is disabled after the first bank active signal is enabled if the mode signal has a second level.

According to an embodiment, a semiconductor device includes a command decoder, a mode register, a refresh signal generator, a mode signal generator and a refresh controller. The command decoder decodes an external command signal to generate a mode register write signal, a refresh pulse signal and a refresh end pulse signal. The mode register receives an information signal in response to the mode register write signal to extract information on a mode from the information signal, stores the information, and outputs the information as a set signal. The refresh signal generator generates a refresh signal in response to the refresh pulse signal and the refresh end pulse signal. The mode signal generator generates a mode signal in response to the refresh signal and the set signal. The refresh controller generates a first bank active signal and a second bank active signal sequentially enabled in response to the mode signal and a section signal. The second bank active signal is enabled while the first bank active signal is enabled if the mode signal has a first level, and the second bank active signal is enabled while the first bank active signal is disabled after the first bank active signal is enabled if the mode signal has a second level.

According to an embodiment, a semiconductor system includes a controller and a semiconductor device. The controller generates an external command signal and an information signal. The semiconductor device generates a mode signal in response to the external command signal and the information signal. The semiconductor device also generates a first bank active signal and a second bank active signal sequentially enabled in response to the mode signal and a section signal. If the mode signal has a first level, the second bank active signal is enabled while the first bank active signal is enabled. If the mode signal has a second level, the second bank active signal is enabled while the first bank active signal is disabled after the first bank active signal is enabled.

### BRIEF DESCRIPTION OF THE DRAWINGS

FIG. 1 is a block diagram illustrating a semiconductor system according to an embodiment of the inventive concept;

FIG. 2 is a block diagram illustrating a refresh controller included in the semiconductor system of FIG. 1;

FIG. 3 is a block diagram illustrating a bank active signal generator included in the refresh controller of FIG. 2;

FIG. 4 is a block diagram illustrating an internal active signal generator included in the bank active signal generator of FIG. 3;

FIGS. 5 and 6 are timing diagrams illustrating operations of the semiconductor system shown in FIG. 1; and

### DETAILED DESCRIPTION

Various embodiments of the inventive concept will be described with reference to the accompanying figures. However, the embodiments described are for illustrative purposes only and are not intended to limit the scope of the inventive concept. Cell capacitors of the DRAM devices have to be periodically recharged to retain or refresh their stored data. This operation may be referred to as a refresh operation. The refresh operation may be performed by activating a word line at least once within a data retention time of the memory cells to amplify the data stored in the memory cells. The data retention time may correspond to a maximum time that the cell capacitors can retain minimum charges which are required to reveal correct logic data without any refresh operations. The refresh operation may be categorized as either an auto-refresh operation or a self-refresh operation. The auto-refresh operation may be executed by refresh commands outputted from a controller that controls the DRAM devices. In addition, the self-refresh operation may be executed by self-refresh signals which are internally generated in the DRAM devices in a power down mode.

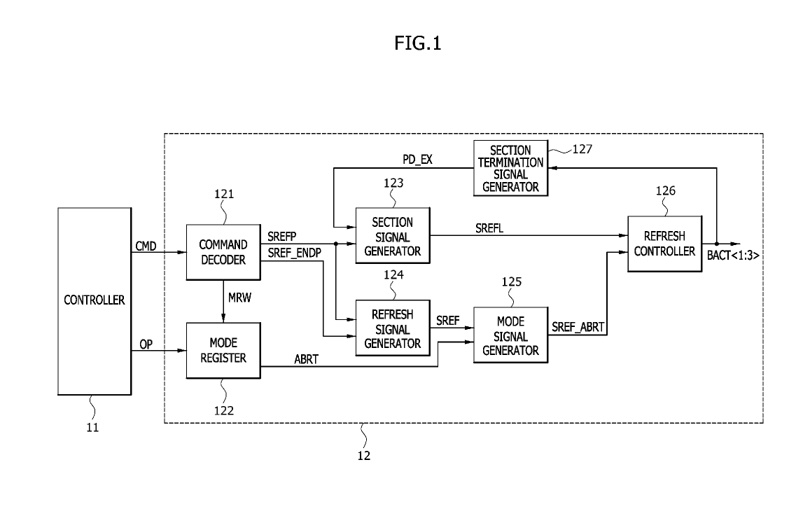

Referring to FIG. 1, a semiconductor system according to an embodiment may be configured to include a controller 11 and a semiconductor device 12. The controller 11 may be configured to apply an external command signal CMD and an information signal OP to the semiconductor device 12. The information signal OP may include information stored in a mode register 122 of the semiconductor device 12 during a mode register set operation. For example, the information signal OP may include information on a latency, a burst length and various modes. The semiconductor device 12 may be configured to include a command decoder 121, a mode register 122, a section signal generator 123, a refresh signal generator 124, a mode signal generator 125, a refresh controller 126 and a section termination signal generator 127.

The command decoder 121 may be configured to decode the external command signal CMD to generate a refresh pulse signal SREFP, a refresh end pulse signal SREF_ENDP and a mode register write signal MRW. The refresh pulse signal SREFP may be generated to activate either a self-refresh mode or an auto-refresh mode. The refresh end pulse signal SREF_ENDP may be generated to terminate either the self-refresh mode or the auto-refresh mode. The mode register write signal MRW may be generated to extract various information from the information signal OP and store the extracted information in the mode register 122.

The mode register 122 may be configured to store the various information extracted from the information signal OP when the mode register write signal MRW is generated. The mode register 122 may be configured to output the information on the modes controlling procedures to execute a refresh operation including the self-refresh operation and the auto-refresh operation as a set signal ABRT. In an embodiment, the set signal ABRT may be generated to have a logic “low” level in a mode that the memory banks are successively refreshed. The set signal ABRT may have a logic “high” level in a mode that the memory banks are separately refreshed one by one. The logic levels of the set signal ABRT may be set to be different according to various embodiments.

The section signal generator 123 may be configured to generate a section signal SREFL in response to the refresh pulse signal SREFP and a section termination signal PD_EX. The section signal SREFL may be enabled to have a logic “high” level if the refresh pulse signal SREFP is generated. In addition, the section signal SREFL may be disabled to have a logic “low” level if the section termination signal PD_EX is generated. The section termination signal PD_EX may be generated in synchronization with a rising edge of a third bank active signal BACT<3>. In an embodiment, the rising edge of the third bank active signal BACT<3> may correspond to a point of time when the third bank active signal BACT<3> is disabled after the third bank active signal BACT<3> is enabled. Logic levels of the enabled section signal SREFL and the disabled section signal SREFL may be set to be different according to various embodiments.

The refresh signal generator 124 may be configured to generate a refresh signal SREF in response to the refresh pulse signal SREFP and the refresh end pulse signal SREF_ENDP. The refresh signal SREF may be enabled to have a logic “high” level if the refresh pulse signal SREFP is generated. Further, the refresh signal SREF may be disabled to have a logic “low” level if the refresh end pulse signal SREF_ENDP is generated. More specifically, the refresh signal SREF may be enabled while a refresh mode is activated by the external command signal CMD. Logic levels of the enabled refresh signal SREF and the disabled refresh signal SREF may be set to be different according to various embodiments.

The mode signal generator 125 may be configured to generate a mode signal SREF_ABRT in response to the refresh signal SREF and the set signal ABRT. A logic level of the mode signal SREF_ABRT may be determined by a logic level of the set signal ABRT while the refresh signal SREF is enabled. The mode signal SREF_ABRT may be generated to have a logic “high” level in response to the set signal ABRT having a logic “low” level in a mode that the memory banks are successively refreshed. In addition, the mode signal SREF_ABRT may have a logic “low” level in response to the set signal ABRT having a logic “high” level in a mode that the memory banks are separately refreshed one by one. The logic levels of the mode signal SREF_ABRT according to the modes that the refresh operations are executed may be set to be different according to various embodiments.

The refresh controller 126 may be configured to generate the first, second and third bank active signals BACT<1:3> which are successively or separately enabled according to a logic level of the mode signal SREF_ABRT while the section signal SREFL is enabled. The refresh controller 126 may successively enable the first, second and third bank active signals BACT<1:3> when the mode signal SREF_ABRT has a logic “low” level. More specifically, the refresh controller 126 may enable the second bank active signal BACT<2> after a predetermined delay time elapses from time that the first bank active signal BACT<1> is enabled. In addition, the refresh controller 126 may enable the third bank active signal BACT<3> after the predetermined delay time elapses from a time that the second bank active signal BACT<2> is enabled. In such a case, an enablement period of the first bank active signal BACT<1> may partially overlap with an enablement period of the second bank active signal BACT<2>. Further, an enablement period of the second bank active signal BACT<2> may partially overlap with an enablement period of the third bank active signal BACT<2>. Accordingly, if the first, second and third bank active signals BACT<1:3> are signals for refreshing first, second and third memory banks respectively, the refresh operations of the first, second and third memory banks may be simultaneously performed during a certain period. The refresh controller 126 may separately enable the first, second and third bank active signals BACT<1:3> when the mode signal SREF_ABRT has a logic “high” level. For instance, the second bank active signal BACT<2> may be enabled to perform the refresh operation of the second memory bank when the first bank active signal BACT<1> is disabled after the first bank active signal BACT<1> is enabled to perform the refresh operation of the first memory bank. Subsequently, after the second bank active signal BACT<2> is disabled, the third bank active signal BACT<3> may then be enabled to perform the refresh operation of the third memory bank.

The section termination signal generator 127 may be configured to generate the section termination signal PD_EX in synchronization with the third bank active signal BACT<3>. More specifically, the section termination signal generator 127 may generate the section termination signal PD_EX in synchronization with a time when the third bank active signal BACT<3> is disabled after the third bank active signal BACT<3> is enabled to perform the refresh operation of the third memory bank.

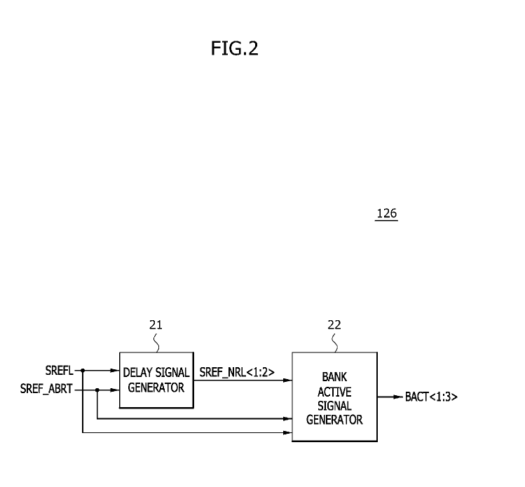

Referring to FIG. 2, the refresh controller 126 may be configured to include a delay signal generator 21 and a bank active signal generator 22. The delay signal generator 21 may repeatedly retard the section signal SREFL in response to the mode signal SREF_ABRT to generate first and second delay signals SREF_NRL<1:2>. When the mode signal SREF_ABRT has a logic “low” level, the delay signal generator 21 may then retard the section signal SREFL by a predetermined delay time to generate the first delay signal SREF_NRL<1>. Further the delay signal generator 21 may retard the first delay signal SREF_NRL<1> by a predetermined delay time to generate the second delay signal SREF_NRL<2>. When the mode signal SREF_ABRT has a logic “high” level, the delay signal generator 21 may be configured to terminate the operation that generates the first and second delay signals SREF_NRL<1:2> from the section signal SREFL. The bank active signal generator 22 may be configured to generate the first, second and third bank active signals BACT<1:3> from the section signal SREFL and the first and second delay signals SREF_NRL<1:2> in response to the mode signal SREF_ABRT. When the mode signal SREF_ABRT has a logic “low” level, the bank active signal generator 22 may be configured to generate the first bank active signal BACT<1> enabled in synchronization with the section signal SREFL. Further, the second bank active signal BACT<2> may be enabled in synchronization with the first delay signal SREF_NRL<1>. In addition, the third bank active signal BACT<3> may be enabled in synchronization with the second delay signal SREF_NRL<2>. When the mode signal SREF_ABRT has a logic “high” level, the bank active signal generator 22 may be configured to generate the first bank active signal BACT<1> enabled in synchronization with the section signal SREFL. Further, the second bank active signal BACT<2> may be enabled in synchronization with the first bank active signal BACT<1>. Moreover, the third bank active signal BACT<3> may be enabled in synchronization with the second bank active signal BACT<2>.

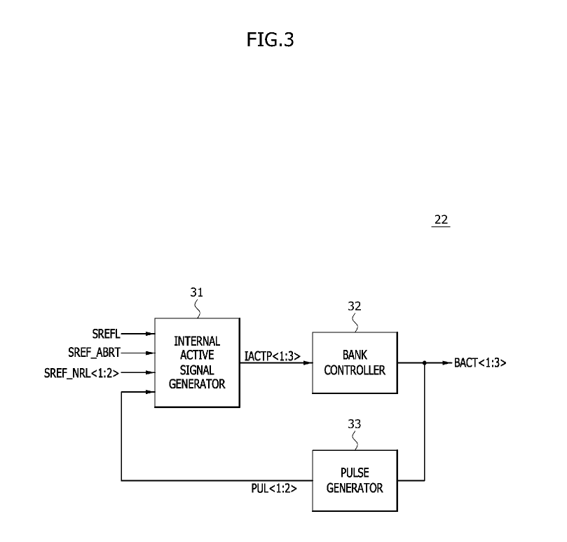

Referring to FIG. 3, the bank active signal generator 22 may be configured to include an internal active signal generator 31, a bank controller 32 and a pulse generator 33. The internal active signal generator 31 may be configured to generate first, second and third internal active signals IACTP<1:3> from the section signal SREFL and the first and second delay signals SREF_NRL<1:2> in response to the mode signal SREF_ABRT. When the mode signal SREF_ABRT has a logic “low” level, the internal active signal generator 31 may be configured to generate the first internal active signal IACTP<1> including a pulse created in synchronization with the section signal SREFL. Further, the second internal active signal IACTP<2> may be generated including a pulse created in synchronization with the first delay signal SREF_NRL<1>. In addition, the third internal active signal IACTP<3> may be generated including a pulse created in synchronization with the second delay signal SREF_NRL<2>. When the mode signal SREF_ABRT has a logic “high” level, the internal active signal generator 31 may be configured to generate the first internal active signal IACTP<1> including a pulse created in synchronization with the section signal SREFL. Further, the second internal active signal IACTP<2> may be generated including a pulse created in synchronization with a first pulse PUL<1>. In addition, the third internal active signal IACTP<3> may be generated including a pulse created in synchronization with a second pulse PUL<2>. The bank controller 32 may be configured to generate the first, second and third bank active signals BACT<1:3> in response to the first, second and third internal active signals IACTP<1:3>. Specifically, the bank controller 32 may be configured to generate the first bank active signal BACT<1> enabled in synchronization with the pulse of the first internal active signal IACTP<1>. Further, the bank controller 32 may generate the second bank active signal BACT<2> enabled in synchronization with the pulse of the second internal active signal IACTP<2>. In addition, the bank controller 32 may generate the third bank active signal BACT<3> enabled in synchronization with the pulse of the third internal active signal IACTP<3>. The pulse generator 33 may be configured to generate the first and second pulses PUL<1:2> in response to the first and second bank active signals BACT<1:2>. More specifically, the pulse generator 33 may be configured to generate the first pulse PUL<1> in synchronization with a time when the first bank active signal BACT<1> is disabled after the first bank active signal BACT<1> is enabled. The pulse generator 33 may also generate the second pulse PUL<2> in synchronization with a time that the second bank active signal BACT<2> is disabled after the second bank active signal BACT<2> is enabled.

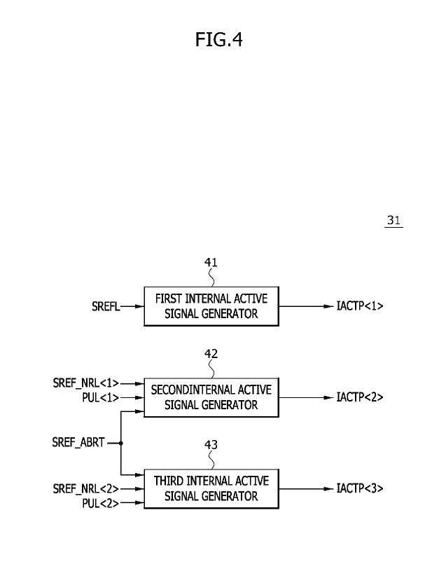

Referring to FIG. 4, the internal active signal generator 31 may be configured to include a first internal active signal generator 41, a second internal active signal generator 42 and a third internal active signal generator 43. The first internal active signal generator 41 may be configured to generate the first internal active signal IACTP<1> including the pulse created in synchronization with a time that the section signal SREFL is enabled to have a logic “high” level. The second internal active signal generator 42 may be configured to generate the second internal active signal IACTP<1> from the first delay signal SREF_NRL<1> or the first pulse PUL<1> in response to the mode signal SREF_ABRT. For instance, the second internal active signal generator 42 may be configured to generate the second internal active signal IACTP<2> in synchronization with a time that the first delay signal SREF_NRL<1> is enabled to have a logic “high” level when the mode signal SREF_ABRT has a logic “low” level. In addition, the second internal active signal generator 42 may generate the second internal active signal IACTP<2> in synchronization with the first pulse PUL<1> when the mode signal SREF_ABRT has a logic “high” level. The third internal active signal generator 43 may be configured to generate the third internal active signal IACTP<3> from the second delay signal SREF_NRL<2> or the second pulse PUL<2> in response to the mode signal SREF_ABRT. For example, the third internal active signal generator 43 may be configured to generate the third internal active signal IACTP<3> in synchronization with a time that the second delay signal SREF_NRL<2> is enabled to have a logic “high” level when the mode signal SREF_ABRT has a logic “low” level. Further, the third internal active signal generator 43 may generate the third internal active signal IACTP<3> in synchronization with the second pulse PUL<2> when the mode signal SREF_ABRT has a logic “high” level.

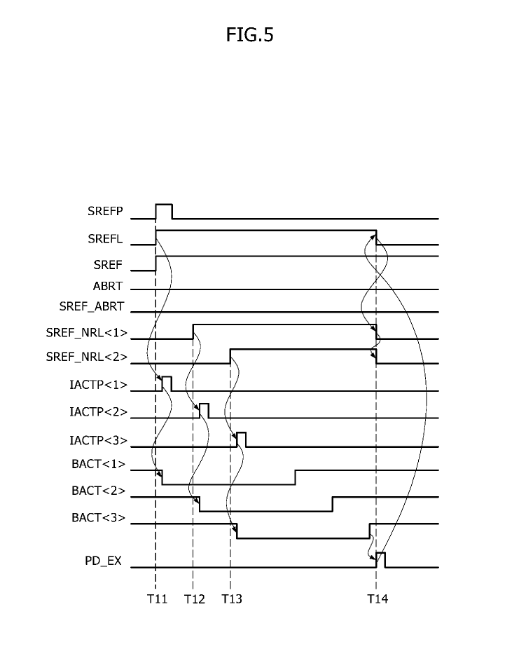

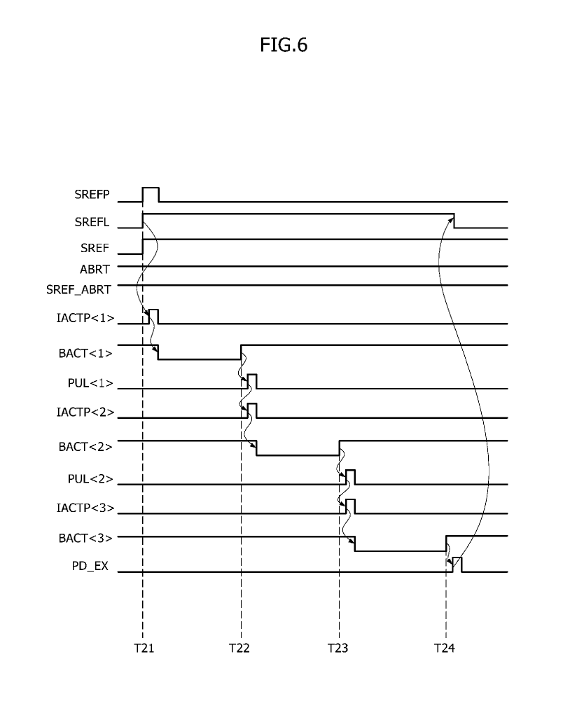

Operations of the semiconductor system having the aforementioned configuration will be described with reference to FIG. 5 illustrating a mode that memory banks are successively refreshed and with reference to FIG. 6 illustrating a mode that the memory banks are separately refreshed one by one.

Referring to FIG. 5, if a pulse of the refresh pulse signal SREFP is created at a time “T11,” the section signal SREFL and the refresh signal SREF may be enabled to have a logic “high” level in synchronization with the pulse of the refresh pulse signal SREFP. In such an instance, the mode register 122 may be configured to output the set signal ABRT having a logic “low” level to execute a mode that the memory banks are successively refreshed. As a result, the mode signal SREF_ABRT may maintain a logic “low” level when the refresh operations are performed. The section signal SREFL may be retarded by a predetermined period to generate the first delay signal SREF_NRL<1> enabled at a time “T12.” In addition, the first delay signal SREF_NRL<1> may be retarded by a predetermined period to generate the second delay signal SREF_NRL<2> enabled at a time “T13.” If the mode signal SREF_ABRT has a logic “low” level, the first internal active signal IACTP<1> may be generated to include a pulse created in synchronization with the section signal SREFL enabled at time “T11.” Further, the second internal active signal IACTP<2> may be generated to include a pulse created in synchronization with the first delay signal SREF_NRL<1> enabled at time “T12.” In addition, the third internal active signal IACTP<3> may be generated to include a pulse created in synchronization with the second delay signal SREF_NRL<2> enabled at time “T13.” The first, second and third bank active signals BACT<1:3> may be successively enabled in synchronization with the pulses of the first, second and third internal active signals IACTP<1:3>, respectively. A pulse of the section termination signal PD_EX may be created in synchronization with a time “T14” that a rising edge of the third bank active signal BACT<3> occurs. The section signal SREFL and the first and second delay signals SREF_NRL<1:2> may be disabled to have a logic “low” level in synchronization with the pulse of the section termination signal PD_EX.

Referring to FIG. 6, if a pulse of the refresh pulse signal SREFP is created at time “T21,” the section signal SREFL and the refresh signal SREF may be enabled to have a logic “high” level in synchronization with the pulse of the refresh pulse signal SREFP. In such an instance, the mode register 122 may be configured to output the set signal ABRT having a logic “high” level to execute a mode that the memory banks are separately refreshed one by one. As a result, the mode signal SREF_ABRT may maintain a logic “high” level when the refresh operations are performed. The first internal active signal IACTP<1> may be generated to include a pulse created in synchronization with the section signal SREFL enabled at the time “T21.” Further, the first bank active signal BACT<1> may be enabled to have a logic “low” level in synchronization with the pulse of the first internal active signal IACTP<1>. The first pulse PUL<1> may be created in synchronization with a time “T22” that a rising edge of the first bank active signal BACT<1> occurs. The second internal active signal IACTP<2> may be generated to include a pulse created in synchronization with the first pulse PUL<1>. In addition, the second bank active signal BACT<2> may be enabled to have a logic “low” level in synchronization with the pulse of the second internal active signal IACTP<2>. The second pulse PUL<2> may be created in synchronization with a time “T23” that a rising edge of the second bank active signal BACT<2> occurs. The third internal active signal IACTP<3> may be generated to include a pulse created in synchronization with the second pulse PUL<2>. In addition, the third bank active signal BACT<3> may be enabled to have a logic “low” level in synchronization with the pulse of the third internal active signal IACTP<3>. A pulse of the section termination signal PD_EX may be created at a time “T24” that a rising edge of the third bank active signal BACT<3> occurs. The section signal SREFL may be disabled to have a logic “low” level in synchronization with the pulse of the section termination signal PD_EX.

As described above, a semiconductor system according to various embodiments may provide two refresh modes. An embodiment may be a mode that memory banks are successively refreshed. Further, an embodiment may also be a mode that the memory banks are separately refreshed one by one. In the mode that the memory banks are separately refreshed one by one, an external command to activate the memory banks may be inputted after a refresh operation of a single bank.

What is claimed is:

1. A semiconductor device comprising:
a mode signal generator suitable for generating a mode signal; and
a refresh controller suitable for generating a first bank active signal and a second bank active signal sequentially enabled in response to the mode signal and a section signal,
wherein the second bank active signal is enabled while the first bank active signal is enabled if the mode signal has a first level, and
wherein the second bank active signal is enabled while the first bank active signal is disabled after the first bank active signal is enabled if the mode signal has a second level.

2. The semiconductor device of claim 1, wherein a logic level of the mode signal is set in response to a set signal while a refresh signal is enabled.

3. The semiconductor device of claim 1, wherein the section signal is enabled in response to a refresh pulse signal and disabled in response to a section termination signal.

4. The semiconductor device of claim 3,
wherein the refresh pulse signal includes a pulse generated in response to an external command signal to activate a refresh mode, and
wherein the section termination signal is generated in synchronization with a point of time that the second bank active signal is disabled after the second bank active signal is enabled.

5. The semiconductor device of claim 1, wherein the refresh controller includes:
a delay signal generator suitable for retarding the section signal in response to the mode signal to generate a delay signal; and
a bank active signal generator suitable for generating the first and second bank active signals in response to the mode signal, the section signal and the delay signal.

6. The semiconductor device of claim 5,
wherein the delay signal is enabled after a predetermined period elapses from when the section signal is enabled, and
wherein the delay signal is disabled when the section signal is disabled.

7. The semiconductor device of claim 5, wherein when the mode signal has the first level, the first bank active signal is enabled in response to the section signal and the second bank active signal is enabled in response to the delay signal.

8. The semiconductor device of claim 7, wherein when the mode signal has the second level, the first bank active signal is enabled in response to the section signal and the second bank active signal is enabled in response to the first bank active signal.

9. The semiconductor device of claim 5, wherein the bank active signal generator includes:
an internal active signal generator suitable for generating a first internal active signal and a second internal active signal in response to the mode signal, the section signal, the delay signal and a pulse;
a bank controller suitable for generating the first and second bank active signals in response to the first and second internal active signals; and
a pulse generator suitable for generating the pulse in response to the first bank active signal.

10. The semiconductor device of claim 9, wherein when the mode signal has the first level, the internal active signal generator is suitable for generating the first internal active signal in response to the section signal and generating the second internal active signal in response to the delay signal.

11. The semiconductor device of claim 10, wherein when the mode signal has the second level, the internal active signal generator is suitable for generating the first internal active signal in response to the section signal and generating the second internal active signal in response to the pulse.

12. The semiconductor device of claim 9, wherein the bank controller is suitable for generating the first bank active signal enabled in response to the first internal active signal and generating the second bank active signal enabled in response to the second internal active signal.

13. The semiconductor device of claim 9, wherein the pulse is generated in synchronization with a point of time when the first bank active signal is disabled after the first bank active signal is enabled.

14. A semiconductor device comprising:
a command decoder suitable for decoding an external command signal to generate a mode register write signal, a refresh pulse signal and a refresh end pulse signal;
a mode register suitable for receiving an information signal in response to the mode register write signal to extract information on a mode from the information signal, storing the information therein, and outputting the information as a set signal;
a refresh signal generator suitable for generating a refresh signal in response to the refresh pulse signal and the refresh end pulse signal;
a mode signal generator suitable for generating a mode signal in response to the refresh signal and the set signal; and
a refresh controller suitable for generating a first bank active signal and a second bank active signal sequentially enabled in response to the mode signal and a section signal,
wherein the second bank active signal is enabled while the first bank active signal is enabled if the mode signal has a first level, and
wherein the second bank active signal is enabled while the first bank active signal is disabled after the first bank active signal is enabled if the mode signal has a second level.

15. The semiconductor device of claim 14, further comprising:
a section signal generator suitable for generating the section signal enabled in response to the refresh pulse signal and disabled in response to a section termination signal.

16. The semiconductor device of claim 15, further comprising:
a section termination signal generator suitable for generating the section termination signal in synchronization with a point of time when the second bank active signal is disabled after the second bank active signal is enabled.

17. A semiconductor system comprising:
a controller suitable for generating an external command signal and an information signal; and
a semiconductor device suitable for generating a mode signal in response to the external command signal and the information signal and generating a first bank active signal and a second bank active signal sequentially enabled in response to the mode signal and a section signal,
wherein the second bank active signal is enabled while the first bank active signal is enabled if the mode signal has a first level, and
wherein the second bank active signal is enabled while the first bank active signal is disabled after the first bank active signal is enabled if the mode signal has a second level.

18. The semiconductor system of claim 17, wherein the semiconductor device includes:
a command decoder suitable for decoding the external command signal to generate a mode register write signal, a refresh pulse signal and a refresh end pulse signal;
a mode register suitable for receiving an information signal in response to the mode register write signal to extract information on a mode from the information signal, storing the information, and outputting the information as a set signal;
a refresh signal generator suitable for generating a refresh signal in response to the refresh pulse signal and the refresh end pulse signal; and
a mode signal generator suitable for generating the mode signal in response to the refresh signal and the set signal.

19. The semiconductor system of claim 18, wherein the semiconductor device further includes a section signal generator suitable for generating the section signal enabled in response to the refresh pulse signal and disabled in response to a section termination signal.

20. The semiconductor system of claim 19, wherein the semiconductor device further includes a section termination signal generator suitable for generating the section termination signal in synchronization with when the second bank active signal is disabled after the second bank active signal is enabled.

21. The semiconductor system of claim 17, wherein the semiconductor device includes:
a delay signal generator suitable for retarding the section signal in response to the mode signal to generate a delay signal; and
a bank active signal generator suitable for generating the first and second bank active signals in response to the mode signal, the section signal and the delay signal.

22. The semiconductor system of claim 21,
wherein the delay signal is enabled after a predetermined period elapses from when the section signal is enabled, and
wherein the delay signal is disabled when the section signal is disabled.

23. The semiconductor system of claim 21, wherein when the mode signal has the first level, the first bank active signal is enabled in response to the section signal and the second bank active signal is enabled in response to the delay signal.

24. The semiconductor system of claim 23, wherein when the mode signal has the second level, the first bank active signal is enabled in response to the section signal and the second bank active signal is enabled in response to the first bank active signal.

25. The semiconductor system of claim 21, wherein the bank active signal generator includes:
an internal active signal generator suitable for generating a first internal active signal and a second internal active signal in response to the mode signal, the section signal, the delay signal and a pulse;
a bank controller suitable for generating the first and second bank active signals in response to the first and second internal active signals; and
a pulse generator suitable for generating the pulse in response to the first bank active signal.

26. The semiconductor system of claim 25, wherein when the mode signal has the first level, the internal active signal generator is suitable for generating the first internal active signal in response to the section signal and generating the second internal active signal in response to the delay signal.

27. The semiconductor system of claim 26, wherein when the mode signal has the second level, the internal active signal generator is suitable for generating the first internal active signal in response to the section signal and generating the second internal active signal in response to the pulse.

28. The semiconductor system of claim 25, wherein the bank controller is suitable for generating the first bank active signal enabled in response to the first internal active signal and generating the second bank active signal enabled in response to the second internal active signal.

29. The semiconductor system of claim 25, wherein the pulse is generated in synchronization with a point of time that the first bank active signal is disabled after the first bank active signal is enabled.
